(19) United States
(12) Patent Application Publication
(10) Pub. No.: US 2008/0268153 A1
(43) Pub. Date: Oct. 30, 2008

(54) Thin-film forming apparatus and thin-film forming method

(75) Inventor: Tetsuya Kitagawa, Miyagi (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO, LTD., Tokyo (JP)

(21) Appl. No.: 12/081,094

(22) Filed: Apr. 10, 2008

(30) Foreign Application Priority Data
Apr. 24, 2007 (JP) 2007-114632

(51) Int. Cl. C23C 16/44

(52) U.S. Cl. 427/255.29; 118/729

(57) ABSTRACT

A thin-film forming method of this invention forms a thin film on a wafer. This method is capable of improving the quality yield of wafers. The thin-film forming method includes the step of suctioning a flow of a film-forming gas from both sides of a conveyance path while conveying a wafer along the conveyance path. The conveyance path extends in a direction of passing through the gas flow.

### BACKGROUND OF THE INVENTION

1. Field of the Invention

The present invention relates to a thin-film forming apparatus and a thin-film forming method for applying a film-forming gas on a wafer to form a thin film thereon.

2. Description of the Related Art

A thin-film forming technology includes not only forming thin films but also realizing various high-order functions, such as an electrical function, an optical function and a mechanical function.

The thin-film forming technology that realizes these high-order functions is an important technology in the semiconductor industry involving transistors. Particularly, importance of the thin-film forming technology is recognized as a process technology for creating a semiconductor circuit element. The reason for such recognition of the thin-film forming technology is that a thin film, which is formed in a semiconductor production process, remains as it is in the device structure, i.e., the thin film has a great influence on the characteristics, yield and reliability of the device.

One known thin-film forming method used in the semiconductor production process is a chemical vapor deposition (CVD) method, and another known method is a physical vapor deposition (PVD) method. A normal pressure CVD method, a reduced-pressure (low-pressure) CVD method, a high-pressure CVD method, a plasma CVD method and a photoexcitation CVD method are proposed as the CVD method. A sputtering method, a vacuum deposition method and an ion plating method are proposed as the PVD method. Usually, any of the above-mentioned thin-film forming methods is selected to form a thin film, in consideration of the type of a thin film to be formed, the quality of the film, mass productivity thereof, and/or other factors.

One example of an apparatus that uses a normal pressure CVD method to form a thin film on a semiconductor wafer heats the semiconductor wafer conveyed on a conveyor, and then blows a film-forming gas from a dispersion head located above the conveyor. The normal pressure CVD apparatus can perform continuous film forming processing by using the conveyor because the pressure within the apparatus does not have to be reduced.

Although the normal pressure CVD apparatus is designed to remove particles and an unreacted film-forming gas through an exhaust duct, some of the particles and unreacted film-forming gas inevitably fall and thereby re-adhere to the semiconductor wafer. Thus, the quality yield of semiconductor wafers is reduced.

One approach for solving the above-described problems is disclosed in Japanese Patent Application Laid-Open (Kokai) No. H09-063971. An exhaust duct is located under a dispersion head with a conveyor therebetween in order to remove (suction) particles and an unreacted film-forming gas from immediately below the dispersion head.

The thin-film forming apparatus of Japanese Patent Application Kokai No. H09-063971 includes a conveyor for conveying a semiconductor wafer, a dispersion head for blowing a film-forming gas, a blower for blowing a nitrogen gas, an etching mechanism for removing reaction products adhered to the conveyor, a heater for heating the wafer, and an exhaust duct for suctioning an unreacted film-forming gas and particles. The exhaust duct is located immediately below the dispersion head with the conveyor therebetween.

The thin-film forming apparatus described in Japanese Patent Application Kokai No. H09-063971 can reduce the adhesion of the particles to the heater and semiconductor wafer. Therefore, the quality yield of semiconductor wafers can be improved. Also, the time required for maintenance of the heater can be reduced.

In the thin-film forming apparatus of Japanese Patent Application Kokai No. H09-063971, the semiconductor wafer passes above the exhaust duct. Therefore, a thin film is formed on the semiconductor wafer by the film-forming gas directly applied (blown) to the wafer (called “direct-made or primary thin film” hereinafter). At the same time, however, another thin film is also formed on the semiconductor wafer by a gas flow of the film-forming gas suctioned by the exhaust duct (called “secondary thin film” hereinafter). The secondary thin film is thinner than the primary thin film. Accordingly, the thickness of the secondary thin film is easily affected by the disturbance of exhaust balance of the exhaust duct.

If the exhaust balance is disturbed by a nick, a dent or the like of the dispersion head, the surface uniformity (flatness) of a thin film formed by the thin-film forming apparatus described in Japanese Patent Application Kokai No. H09-063971 becomes extremely worse. FIG. 1A of the accompanying drawings shows one example of the surface of such thin film. The recessed and projecting parts 11a, 11b, 11c, 11d, 11e that are circled in FIG. 1A correspond to the linear unevenness 12a, 12b, 12c, 12d, 12e (called “film stripes” hereinafter) formed on a wafer 10 in FIG. 1B. The film stripes 12a to 12e are defects that are visible to naked eyes of a human.

### SUMMARY OF THE INVENTION

It is one object of the present invention to provide a thin-film forming apparatus and a thin-film forming method that are capable of improving the quality yield of wafers by preventing the generation of film stripes.

According to a first aspect of the present invention, there is provided a thin-film forming apparatus that applies a film-forming gas onto a wafer to form a thin film on the wafer. The thin-film forming apparatus includes a gas supply part that supplies a gas flow of the film-forming gas via supply ports, and a conveyor that conveys the wafer along a conveyance path passing through the gas flow. The thin-film forming apparatus also includes an exhaust part that suctions the gas flow. The exhaust part has at least two exhaust ports that are located respectively on both sides of the conveyance path to suction the gas.

Because the exhaust ports are provided on both sides of the conveyance path, the film-forming gas is removed (i.e., suctioned by the exhaust ports) before it creates secondary films on the wafer. Therefore, the generation of film stripes can be prevented and the quality yield of wafers can be improved.

The gas supply part may have a supply head. The supply head may have the supply ports open in its end face. The exhaust part may have an exhaust head. The exhaust head may have the exhaust ports open in its end face. The supply head and the exhaust head may be integrated as a single element.

The thin-film forming apparatus may have a heater that is provided opposite the supply ports. The conveyance path may extend between the heater and the supply ports.

The film-forming gas may consist of a combination of O₃ and TEOS, or a combination of O₃, TEOS, TMOP and TEB.

According to a second aspect of the present invention, there is provided a thin-film forming method for forming a thin film on a wafer as the wafer is conveyed along a conveyance path passing through a gas flow of a film-forming gas. The thin-film forming method includes the step of suctioning the gas flow of the film-forming gas by means of at least two exhaust ports that are provided respectively on both sides of the conveyance path.

The exhaust ports are provided respectively on both sides of the conveyance path, and the film-forming gas is suctioned by the exhaust ports before it creates secondary films on the wafer. Therefore, the generation of film stripes can be prevented and the quality yield of wafers can be improved.

These and other objects, aspects and advantages of the present invention will become apparent to those skilled in the art from the following detailed description and appended claims when read and understood in conjunction with the accompanying drawings.

### BRIEF DESCRIPTION OF THE DRAWINGS

FIG. 1A is a graph showing surface irregularity of a thin film formed by a conventional thin-film forming apparatus;

FIG. 1B is a top view of a wafer having stripes on its surface, which correspond to the graph of FIG. 1A;

FIG. 2 is a schematic diagram of a thin-film forming apparatus according to an embodiment of the present invention;

FIG. 3 is an enlarged perspective view of a part of the apparatus shown in FIG. 2, which is surrounded by a dashed line 3;

FIG. 4 is a bottom view of a dispersion head and an exhaust head of the thin-film forming apparatus shown in FIG. 2;

FIG. 5 is a cross-sectional view taken along a dashed line 5 in FIG. 3 and FIG. 4;

FIG. 6A is a cross-sectional view taken along a dashed line 6a in FIG. 3 and FIG. 4; and

FIG. 6B is a cross-sectional view taken along a dashed line 6b in FIG. 3 and FIG. 4.

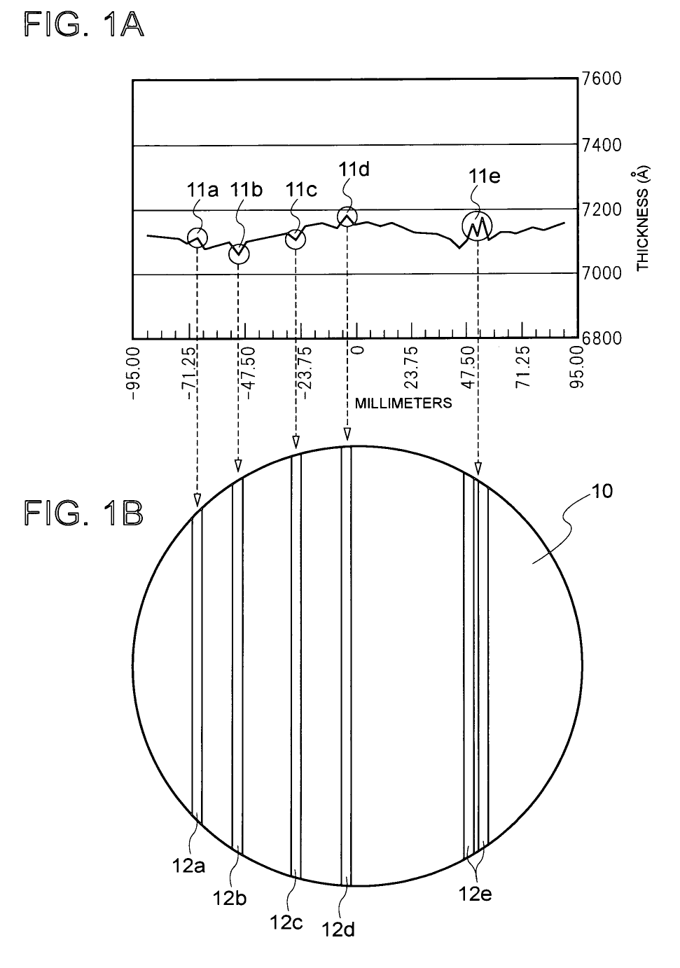

### DETAILED DESCRIPTION OF THE INVENTION

An embodiment of the present invention will be described hereinafter in detail with reference to the drawings.

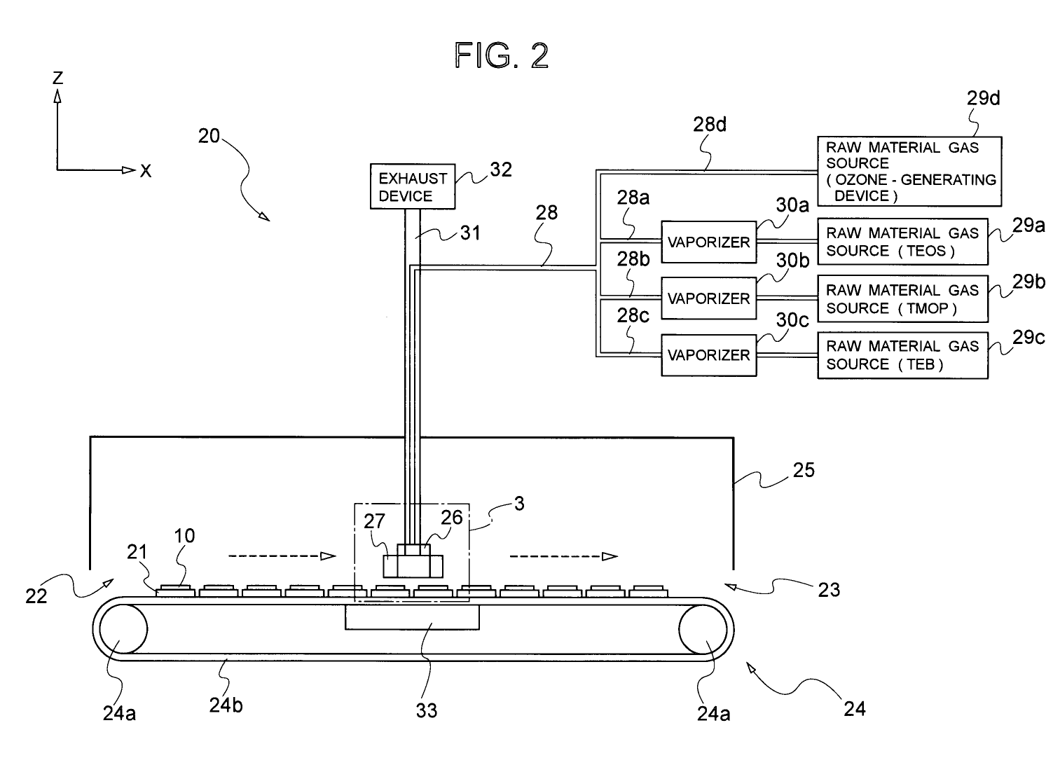

Referring to FIG. 2, a structure of a thin-film forming apparatus 20 according to one embodiment of the present invention will be described. The thin-film forming apparatus 20 is, for example, an O₃(ozone)-TEOS(tetraethoxysilane:Si(OC₂H₅)₄)-CVD apparatus.

The thin-film forming apparatus 20 includes a conveying device 24 that conveys a wafer 10 placed on a tray 21 from a loading portion 22 to an unloading portion 23. In the illustrated embodiment, the conveying device 24 is a belt conveyor unit having a pair of rollers 24a and a belt 24b. It should be noted that the conveying device 24 is not limited to a belt conveyor. For example, the conveying device 24 is a roller conveyor. It should also be noted that, depending on the type of the conveying device 24, the wafer 10 may directly be put on the conveying device 24 without the tray 21. An overhead cover 25 is provided above the conveying device 24 so as to cover the entire conveying device 24. The cover 25 prevents the adhesion of outside dusts to the wafer 10 and improves the heating efficiency of a heating device (will be described). The loading station 22 may be provided with a loading device (not shown) for transporting the tray 21, on which the wafer 10 is carried, onto the belt 24b. The unloading station 23 may be provided with an unloading device (not shown) for taking the tray 21, on which the wafer 10 is placed, from the belt 24b. Therefore, the wafer 10 is conveyed from left to right (i.e., along the direction of an X-axis) sequentially, as shown by the dashed arrows in FIG. 2.

A dispersion head 26 with supply ports for supplying a film-forming gas downward (i.e., to the wafer 10) and an exhaust head 27 with exhaust ports for suctioning a film-forming gas flow are provided above the center of the conveying device 24. The dispersion head 26 and the exhaust head 27 may be integrated as a single unit by providing the exhaust head 27 around the dispersion head 26. Alternatively, the dispersion head 26 and the exhaust head 27 may be provided independently for the sake of exhaust balance. Raw material gas sources 29a, 29b, 29c, 29d are connected to the dispersion head 26 via a supply line 28 to supply film-forming gases. The supply line 28 has four branch lines 28a, 28b, 28c, 28d that are connected to the four gas sources 29a, 29b, 29c, 29d, respectively. TEOS, TMOP (trimethyl phosphate: PO(OCH₃)₃) and TEB (triethoxyborane: B(OC₂H₅)₃) may be accumulated in liquid form in the raw material gas sources 29a, 29b, 29c, respectively. The raw material gas source 29d may be an ozone-generating device. The liquid TEOS, TMOP and TEB that are accumulated respectively in the raw material gas sources 29a to 29c are gasified by vaporizers 30a to 30c connected to the raw material gas sources 29a to 29c respectively, and then are supplied to the dispersion head 26. The ozone, TEOS, TMOP and TEB that are supplied through the supply line 28 are mixed in the dispersion head 26. The mixed film-forming gases are supplied as a gas flow directed toward the wafer 10 from the dispersion head 26 (i.e., vertically downward). The detail of this will be described later.

Sometimes the TMOP and TEB are not used, depending on the type of a thin film to be formed. In such case, supply of the gases may be stopped using valves (not shown) provided on the branch lines 28b and 28c of the supply line 28. It should be noted that raw material gases other than the above-mentioned gases may be used in accordance with the type of a thin film to be formed.

In this specification, the dispersion head 26, the supply line 28 and the raw material gas sources 29a through 29d are collectively called “gas supply part.”

An exhaust device 32 is connected to the exhaust head 27 via an exhaust line 31. The exhaust device 32 may have a fan and a filter, and can discharge the film-forming gases suctioned by exhaust ports to the outside of the thin-film forming apparatus 20 via the exhaust line.

A heating device 33 is provided under the conveyance path of the conveying device 24 (i.e., under the belt 24b). The heating device 33 may be an electric heater. The heating device 33 may be capable of changing the heating temperature of a substrate in accordance with the type of a thin film to be formed. It should be noted that the location of the heating device 33 is not limited to under the conveyance path. For example, the heating device 33 may be provided above the conveyance path. The heating device 33 is not necessarily provided as long as the sufficiently heated wafer is conveyed, but it is preferred that the heating device 33 be provided considering that the heating temperature is changed or adjusted as described above.

Having the above-described configuration, the O₃-TEOS-CVD apparatus 20 can form any one of three thin films, that is, O₃-TEOS-NSG (Non Doped Silicate Glass), O₃-TEOS-BPSG (Boro Phospho Silicate Glass) and O₃-TEOS-PSG (Phospho Silicate Glass), on the wafer 10 by using a selected mixture of the four raw material gases O₃, TEOS, TMOP and TEB.

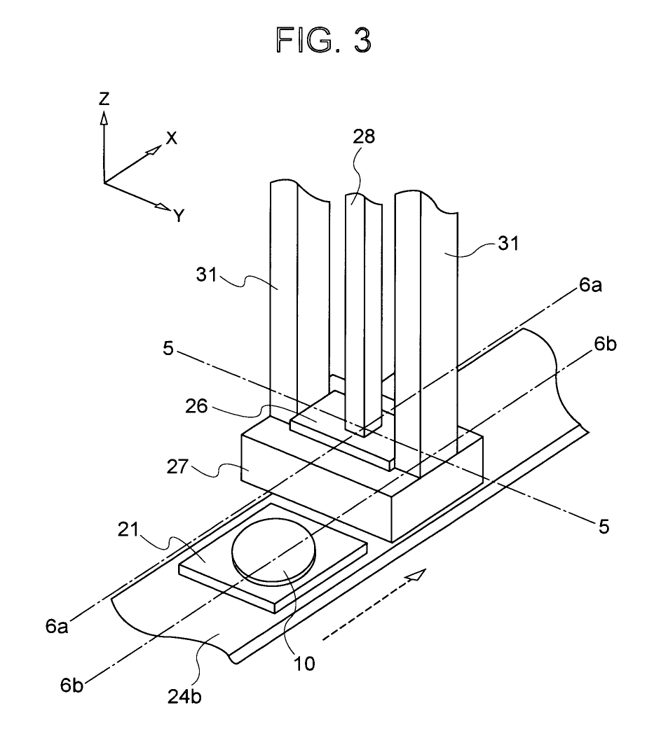

Next, the dispersion head 26 and the exhaust head 27 will be described in detail with reference to FIG. 3 through FIG. 6B.

FIG. 3 is an enlarged perspective view of a dashed square 3 shown in FIG. 2. In this drawing, only one wafer 10 and one tray 21 are illustrated for the sake of convenience.

As shown in FIG. 3, the supply line 28 is connected to a top surface of the dispersion head 26. The exhaust head 27 surrounds the dispersion head 26. Two exhaust lines 31 extend from the top surface of the exhaust head 27. It should be noted that a plurality of supply lines 28 may be connected to the dispersion head 26 to introduce the raw material gases to the dispersion head 26 separately.

The belt 24b passes immediately below the dispersion head 26. Therefore, the belt 24b passes through a gas flow directed downward from the dispersion head 26.

The belt 24b conveys the wafer 10 placed on the tray 21 from the lower left to the upper right (i.e., along the direction of the X-axis) in FIG. 3 as shown by the dashed arrow. The wafer 10 is conveyed along the center of the belt 24b in the direction of the dashed arrow, and thereby passes immediately below the dispersion head 26.

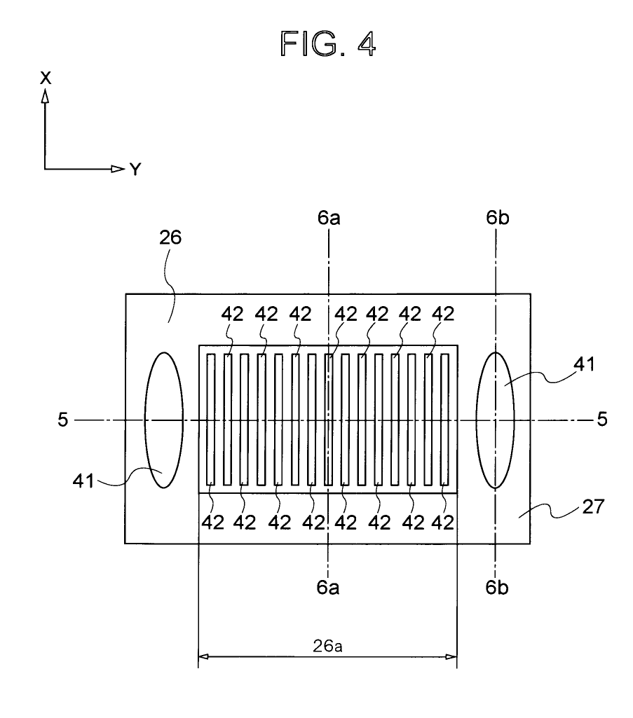

FIG. 4 illustrates a bottom view of the dispersion head 26 and the exhaust head 27.

As shown in FIG. 4, the exhaust head 27 has two exhaust ports 41. Each exhaust port 41 has a substantially oval cross-sectional shape. The two exhaust ports 41 are provided near two short sides of the rectangular dispersion head 26, respectively. The major axis of the oval port 41 extends in the X-axis direction. For example, the distance between the exhaust ports 41 is 30 cm to 32 cm in order to convey the wafer 10 between the exhaust ports 41. It should be noted that the cross-sectional shape, number and positions of the exhaust ports 41 are not limited to those shown in FIG. 4 as long as the exhaust balance can be kept in a suitable condition and a thin film can be formed evenly on the wafer 10. For example, each exhaust port 41 may have a circular cross-sectional shape and be provided on each of the four corners of the exhaust head 27.

The dispersion head 26 has a plurality of supply ports 42 for supplying gas flows of the film-forming gases. For example, the supply ports 42 may have an elongated rectangular cross-sectional shape and be provided in parallel in the direction of the narrow side of the dispersion head 26 (i.e., the direction of the X-axis). The cross-sectional shape, number and positions of the supply ports 42 are not limited to those shown in FIG. 4 as long as a thin film can be formed evenly on the wafer 10. For example, the supply ports 42 may be provided in parallel in the direction of the long side of the dispersion head 26 (i.e., the direction of a Y-axis). The supply ports 42 may be provided in the form of a lattice as a whole. Because the gas flows of the film-forming gases are supplied to the wafer 10 from the dispersion head 26, the width 26a of the dispersion head 26 in the direction traverse to the wafer conveying direction (i.e., the direction of the Y-axis) is preferably wider than the width of the wafer 10.

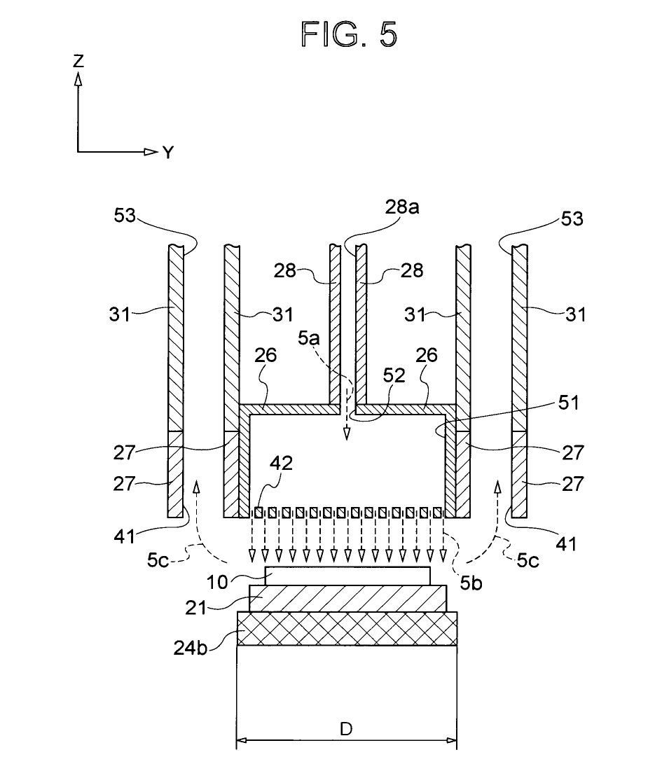

FIG. 5 illustrates a cross-sectional view taken along a dashed line part 5 in FIG. 3 and FIG. 4. It should be noted that, for the sake of convenience, the position of the wafer 10 and the position of the tray 21 that are shown in this drawing assume that the wafer 10 is now immediately below the dispersion head 26.

As shown in FIG. 5, the dispersion head 26 has a main body (or mixing space) 51 for mixing the film-forming gases in the dispersion head 26. An upper part of the dispersion head 26 has an introduction hole 52 for introducing the various raw material gases to the mixing space 51. The inlet 52 of the dispersion head 26 is connected to an outlet 28a of the supply line 28. The dashed arrow 5a indicates a flow of raw material gases introduced from the supply line outlet 28a to the dispersion head main body 51. The suction openings 41 of the suction head 27 are connected to inlets 53 of the respective exhaust lines 31.

As described above, the various raw material gases that are introduced to the dispersion head main body 51 are mixed to obtain a film-forming gas. The film-forming gas is caused to flow out downward from the supply ports 42 by the various raw material gases that are introduced successively. In this manner, gas flows of the film-forming gases directed downward are generated. The gas flows of such film-forming gases are shown by the dashed arrows 5b. The downward gas flows of the film-forming gases are constantly generated by continuously introducing the raw material gases to the dispersion head 26.

Because the exhaust device 32 is connected to the suction head 27 via the exhaust lines 31, the film-forming gases are suctioned upward from the suction ports 41 of the suction head 27 by activating the exhaust device 32 (i.e., the gas flows of the film-forming gases are drawn (pulled) to the upper part of the apparatus 20). The dashed lines 5c show how the gas flows of the film-forming gases are suctioned.

As shown in FIG. 5, the suction ports 41 are provided on both sides of the wafer 10. The suction ports (exhaust ports) 41 are open above the belt 24b. The distance between the exhaust ports 41 is greater than the width D of the belt 24b. The width 26a of the dispersion head 26 is substantially equal to the width D of the belt 24b. The face of the belt 24b is perpendicular to the gas flow direction shown by the dashed arrows 5b. The gas flow direction 5b is substantially vertical downward. The wafer 10 is conveyed by the belt 24b in the direction of passing through only the gas flows of the film-forming gases supplied from the dispersion head 26, and the top surface of the wafer 10 does not intervene with the flows of the film-forming gases pulled toward the exhaust ports 41. It should be noted that the locations of the exhaust ports 41 are not limited to those illustrated in FIG. 5. For example, the exhaust ports 41 may be open at the same height as or below the conveyance pathway of the wafer 10.

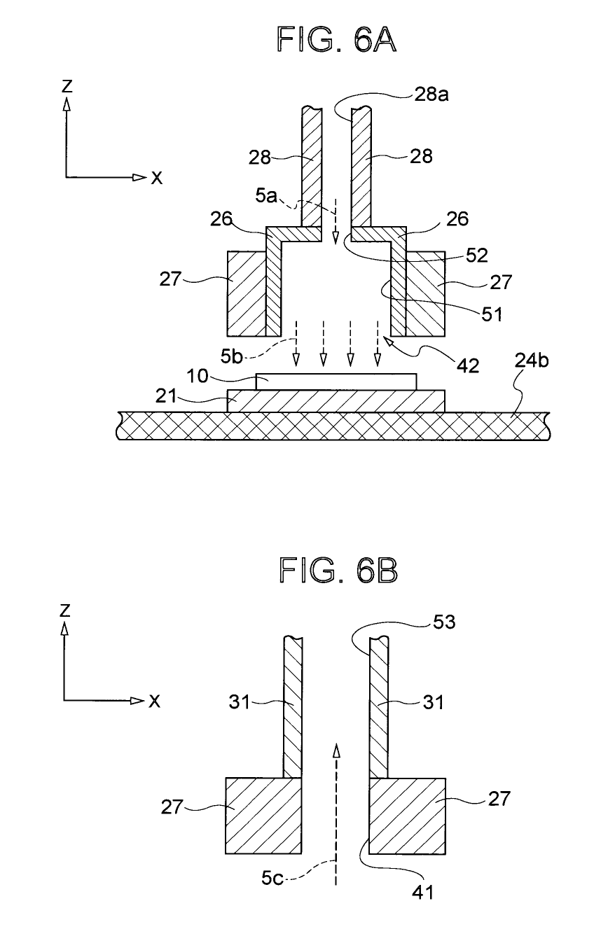

FIG. 6A and FIG. 6B show cross-sectional views taken along the dashed lines 6a and 6b shown in FIG. 3 and FIG. 4, respectively. For the sake of convenience, the position of the wafer 10 and the position of the tray 21 that are shown in the drawings assume that the wafer 10 is now below the dispersion head 26.

In FIG. 6A, the dashed arrow 5a indicates a flow of the raw material gases introduced to the mixing space 51 of the dispersion head 26. The dashed arrows 5b indicate the gas flows of the film-forming gases from the dispersion head 26.

As shown in FIG. 6A, because the exhaust ports 41 do not exist on and above the conveyance pathway of the wafer 10, the wafer 10 does not intervene with the flows of the film-forming gases toward the exhaust ports 41. Because the wafer 10 is conveyed along the X-axis direction, the entire top surface of the wafer 10 is subjected to the gas flows of the film-forming gases supplied from the dispersion head 26.

The dashed arrow 5c in FIG. 6B shows the gas flow suctioned into one of the exhaust ports 41. Because the wafer 10 does not pass below the exhaust ports 41, the wafer 10 does not intervene with the flow of the film-forming gas directed to the exhaust ports 41.

By using the arrangement of the belt 24b and discharge ports 41 as shown in FIG. 4 through FIG. 6B, the wafer 10 passes below the dispersion head 26 without passing below the discharge ports 41. The wafer 10 is conveyed in the direction of passing through the flows of the film-forming gases supplied from the dispersion head 26.

Therefore, the gas flows shown by the dashed arrows 5c do not form a thin film (i.e., a secondary thin film) on the top surface of the wafer 10 that is heated by the heating device 33 while being conveyed on the belt 24b. Only the gas flows shown by the dashed arrows 5b form a thin film (i.e., a direct thin film) on the wafer 10. Therefore, a thin film is evenly formed on the wafer 10. Even if exhaust balance is lost, it does not affect the flatness of the thin film to be formed on the wafer 10 because the gas flows 5c do not create a secondary film on the wafer 10.

As described above, according to the thin-film forming apparatus and the thin-film forming method of the present embodiment, the exhaust ports are provided respectively on both sides of the conveyance path so that the generation of stripes on a wafer (film stripes) can be prevented and the quality yield of wafers can be improved.

It should be noted that the present invention is not limited to the thin-film forming apparatus and thin-film forming method that use the normal pressure CVD method described in the present embodiment. The present invention encompasses a thin-film forming apparatus and a thin-film forming method that use other CVD method.

This application is based on Japanese Patent Application No. 2007-114632 filed on Apr. 24, 2007 and the entire disclosure thereof is incorporated herein by reference.

What is claimed is:

1. A thin-film forming apparatus, which applies a film-forming gas onto a wafer to form a thin film on the wafer, the thin-film forming apparatus comprising:
a gas supply part that supplies a gas flow of the film-forming gas via supply ports;
a conveying part that conveys the wafer along a conveyance path passing through the gas flow; and
an exhaust part that exhausts the gas flow,
wherein the exhaust part has at least two exhaust ports that are disposed respectively on both sides of the conveyance path to suction the gas flow.

2. The thin-film forming apparatus according to claim 1, wherein the gas supply part has a supply head, the supply head has said supply ports which open in an end face of the supply head, the exhaust part has an exhaust head, the exhaust head has said exhaust ports which open in an end face of the exhaust head, and the supply head is directly joined with the exhaust head.

3. The thin-film forming apparatus according to claim 1, further comprising a heater that is located in the vicinity of the supply ports to heat the wafer, wherein the heater is disposed opposite the supply ports, with the conveyance path therebetween.

4. The thin-film forming apparatus according to claim 1, wherein the film-forming gas consists of O₃ and TEOS.

5. The thin-film forming apparatus according to claim 1, wherein the film-forming gas consists of O₃, TEOS, TMOP and TEB.

6. The thin-film forming apparatus according to claim 2, wherein the supply head traverses over the conveyance path, and a width of the supply head in the traverse direction is substantially equal to a width of the wafer.

7. The thin-film forming apparatus according to claim 1, wherein the thin-film is formed by chemical vapor deposition.

8. The thin-film forming apparatus according to claim 1, wherein the wafer has a width in a transverse direction to the conveyance path, and a distance between the exhaust ports is greater than the width of the wafer.

9. The thin-film forming apparatus according to claim 1, wherein the exhaust ports open at or above the height of the conveyance path.

10. The thin-film forming apparatus according to claim 1, wherein the exhaust part suctions the film-forming gas such that the film-forming gas does not intervene with conveyance of the wafer.

11. A thin-film forming method for conveying a wafer along a conveyance path passing through a flow of a film-forming gas, to form a thin film on the wafer, the thin-film forming method comprising the step of suctioning the flow of the film-forming gas by means of at least two exhaust ports that are provided respectively on both sides of the conveyance path.

12. The thin-film forming method according to claim 11, further comprising the step of heating the wafer on the conveyance path from below the conveyance path.

13. The thin-film forming method according to claim 11, wherein the film-forming gas consists of O₃ and TEOS.

14. The thin-film forming method according to claim 11, wherein the film-forming gas consists of O₃, TEOS, TMOP and TEB.

15. The thin-film forming method according to claim 11, wherein the thin-film is formed by chemical vapor deposition.

16. The thin-film forming method according to claim 11, wherein the suctioning step suctions the film-forming gas such that the film-forming gas does not intervene with conveyance of the wafer.
